(19) United States
(12) Patent Application Publication
(10) Pub. No.: US 2007/0121955 A1
(43) Pub. Date: May 31, 2007

(54) Room acoustics correction device

(75) Inventors: James David Johnston, Redmond, WA (US); Sergey Smirnov, Redmond, WA (US)

Correspondence Address: SHOOK, HARDY & BACON L.L.P.;(c/o MICROSOFT CORPORATION), INTELLECTUAL PROPERTY DEPARTMENT, 2555 GRAND BOULEVARD, KANSAS CITY, MO, 64108-2613, US

(73) Assignee: Microsoft Corporation, Redmond, WA (US)

(21) Appl. No.: 11/289,328

(22) Filed: Nov. 30, 2005

(51) Int. Cl. H04R 29/00; H03G 3/00

(52) U.S. Cl. 381/56; 381/61

(57) ABSTRACT

A method and system are provided for improving the preferred listening environment of a sound system. Initially, a calibration pulse is generated from one or more rendering devices. Next, the calibration pulse is captured at a microphone attached to the rendering devices. Thereafter, one or more time delay, gain, and frequency response characteristics of the sound system are calculated using the captured calibration pulse. Based on these calculations, the time delay, gain, and frequency response characteristics of the rendering devices are adjusted respectively to cause the sound generated from the rendering devices to reach a listener's acoustic preference.

### CROSS-REFERENCE TO RELATED APPLICATIONS

None

### STATEMENT REGARDING FEDERALLY SPONSORED RESEARCH OR DEVELOPMENT

None.

### BACKGROUND

Home entertainment systems have moved from simple stereo systems to multi-channel audio systems, such as surround sound systems, and to systems with video displays. Although these home entertainment systems have improved, room acoustics still suffer from deficiencies such as sound distortion caused by reflections from surfaces in a room and/or non-uniform placement of loudspeakers in relation to a listener. Because home entertainment systems are widely used in homes, improvement of acoustics in a room is a concern for home entertainment system users in order to better enjoy their preferred listening environment.

Conventional room acoustics correction devices are highly complex and expensive. These correction devices also require burdensome calibration procedures prior to use for correcting sound distortion deficiencies.

Accordingly, room acoustics correction devices should be simple and inexpensive. Room acoustics correction device should also reliably probe the listening environment of the listener.

### SUMMARY

In an embodiment, a system and method are provided for calibrating a sound audio system in a room to improve the sound quality of what a listener actually hears by integrating applications of acoustics and audio signal processing.

In another embodiment, a probe signal (e.g. a broadband pulse) is provided that has a first arrival portion for measuring the gain of the first arrival signal rather than the overall gain to make corrections via multiple correction filters. The first arrival portion of the captured pulse is measured directly from a rendering device and records the pulse at a microphone to better capture what a listener would actually hear.

In still another embodiment, calibration components are provided for adjusting the gain and time delays, canceling first reflections, and applying a correction filter for correcting the frequency response for each rendering devices. A way for calibrating the rendering devices without injecting pre-echo into the system is also provided.

In yet another embodiment, frequency response and gain characteristics for a set of speakers can be balanced, including corrections based on the location of bad rear/side speaker locations. The phase of a subwoofer can also be aligned to the phase of the main speakers at the listening position.

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter.

### BRIEF DESCRIPTION OF THE DRAWINGS

The present invention is described in detail below with reference to the attached drawings figures, wherein:

FIG. 1 is a block diagram illustrating a calibration module for automatic acoustic calibration in accordance with an embodiment of the invention;

FIG. 2 is a flow chart illustrating a calibration method in accordance with an embodiment of the invention;

FIG. 3 is a flow chart illustrating a calibration method in accordance with an embodiment of the invention.

### DETAILED DESCRIPTION

Embodiments of the present invention are directed to a method and system for improving the acoustics in a room for listening to an audio system such as a stereo, 5.1, 7.1 or larger acoustic system. The room acoustics correction device should selectively capture time delay differences, first-arrival gain differences, differences in speaker timbre (e.g. frequency response), cancel first reflections, and apply the necessary corrections to restore good imaging to stereo and multi-channel audio. The acoustic system includes a source, a computing device, and at least one rendering device (e.g. a speaker). The source can include an audio or an audio-visual (A/V) device (e.g. CD player). In an embodiment, the calibration system includes a calibration computing device, at least one microphone, at least one selected rendering device, and a calibration module located in the calibration computing device.

Furthermore, embodiments of the present invention are directed to a system and method for improving the acoustics in an audio or an audio-visual (A/V) environment. In particular, multiple source devices are connected to multiple rendering devices. The rendering devices include speakers. The source devices may include a calibration computing device. The calibration computing device includes a calibration module that is capable of interacting with a microphone and speaker set for calibration purposes.

Calibration Computing Components

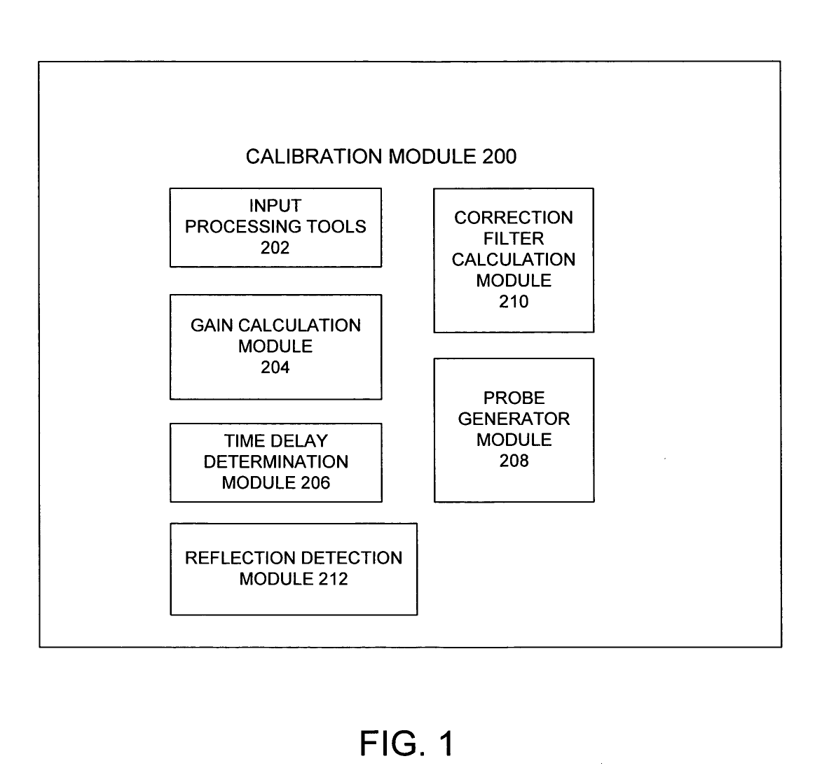

FIG. 1 illustrates a calibration module 200 for calibrating the system from the calibration computing device. The calibration module 200 may be incorporated in a memory of the calibration computing device such as RAM or other memory devices. The calibration module 200 may include input processing tools 202, a gain calculation module 204, a time delay determination module 206, a probe generator module 208, correction filter calculation module 210, and a reflection detection module 212.

In an embodiment, the input processing tools 202 receive a test signal returned from each rendering device. The probe generator module 208 ensures that each speaker has an opportunity to generate a test signal at a precisely selected time. Once the test signal is captured at a microphone, the test signal is transmitted to calibration computing device. At the calibration computing device, the calibration module 200 processes the test signal via the modules that are stored within the calibration module 200. The gain calculation module 204 determines the relative gain level of the first arrival signal from each rendering device and generates a correction gain for each rendering device. The time delay determination module 206 adjusts the relative time delays and inverse delays to be the same for each rendering device. The correction filter calculation module 210 generates a filter that adjusts the total room/speaker response of each rendering device to reach a closer normalized frequency response. The reflection detection module 212 detects a first reflection of a signal and cancels the first reflection.

Techniques for performing these functions are further described below in conjunction with the description of the surround-sound system application. Additionally, these techniques may be applied to other embodiments such as a stereo system and other types of audio speaker systems.

Calibration Methods

In an embodiment, the calibration module calculates the relative gain and relative time delays and determines the frequency response of the system. The relative time delays are calculated by the time differences of the peaks that correspond to the pulses emitted from each rendering device. Preferably, the rendering devices include speakers. By observing the time difference between the analytic energy envelope of the pulses emitted from each rendering device, the first response for each rendering device can be discovered. The relative gains are calculated by measuring a portion of the total power (RMS) that corresponds to the analytic signal around the first peak of each rendering device. A recursive filter cancels the first reflections. The recursive filter cancels the reflections by applying a band-limited signal with an inverted sign. These calculations are used to generate a room correction profile that corresponds to the calculated relative gain, time delays, frequency response of the system, and an inverse filter to correct frequency errors. The room correction profile is stored in memory of the system. Thereafter, the room correction profile is processed with audio content to apply the appropriate adjustments. As a result, the signal reaches the listening position from each rendering device independent of the exact position and properties of that rendering devices or from the room acoustics.

In one embodiment, a central processing unit (CPU) can be used to process the room correction profile. Alternatively, a digital signal processor (DSP) may be used to process the room correction profile. In either embodiment, processing the room correction profile may be accomplished by adjusting the time delay, gain, frequency response characteristics of the rendering devices, and adding a reflection compensation signal to improve the sound generated from the rendering devices based on the microphone quality. In an embodiment, the gain, delays and frequency response values may be adjusted such that these values are similar to each rendering device for a microphone of poor quality. In an alternate embodiment, the gain, delays and frequency response values may be adjusted such that these values are set to a uniform delay, gain, and flat frequency response for a microphone of a high quality.

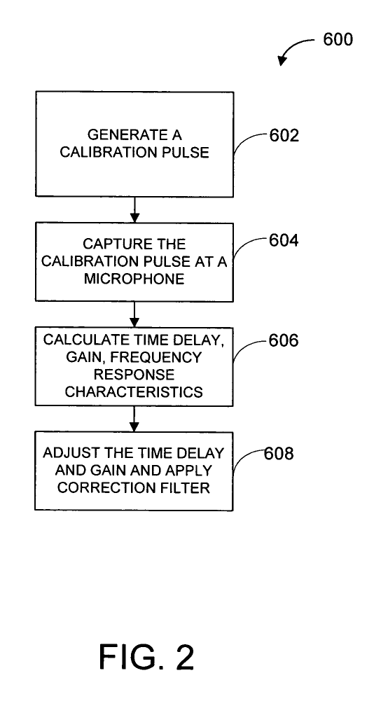

FIG. 2 is an exemplary embodiment showing a flow chart 600 illustrating a calibration process performed with a calibration module 200. At a step 602, a calibration pulse is generated from one or more rendering devices. Preferably, the calibration pulse has energy spread over several thousand samples, good autocorrelation properties, and frequency content similar to that of the rendering devices central frequency response. Additionally, the calibration pulse has an auto-convolution peak and a bandwidth complementary to the noise floor in the space. The pulse is sent through each rendering device in sequence. At a step 604, the calibration pulses are captured at a microphone attached to the calibration computing device. At a step 606, one or more time delay, gain, and frequency response characteristics of the sound system are calculated using the first arrival portion of the captured calibration pulse. At a step 608, the time delay, gain, and frequency response characteristics of the rendering devices are adjusted respectively to cause the sound generated from the rendering devices to reach reference performance characteristics. Additionally, at a step 608, a correction filter may be applied to cancel large reflections observed in the channel.

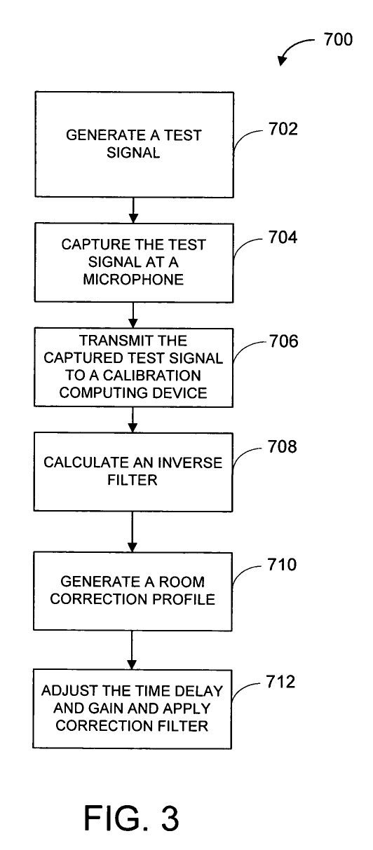

FIG. 3 is an exemplary embodiment showing a flow chart 700 illustrating a calibration process performed with a calibration module 200. At a step 702, a test signal is generated from one or more rendering devices. At a step 704, the test signal is captured at a microphone attached to the calibration computing device. At a step 706, the captured test signal is transmitted to the calibration computing device. At a step 708, an inverse filter is calculated using the first arrival portion of the captured test signal at the calibration computing device. At a step 710, a room correction profile is generated at the calibration computing device. At a step 712, the time delay, gain, and frequency response characteristics of the rendering devices are adjusted respectively using the room correction profile. Additionally, at a step 712, a correction filter may be applied to correct delays and frequency errors.

In an embodiment, the inverse filter can be calculated using the following steps. At a step 708(a), a first LPC prediction filter is calculated by flattening a frequency spectrum at low frequencies. At a step 708(b), a second LPC prediction filter is calculated by flattening a frequency spectrum at high frequencies. At a step 708(c), the first LPC filter is convolved with the second LPC filter to generate an inverse filter.

In some instances the aforementioned steps could be performed in an order other than that specified above. The description is not intended to be limiting with respect to the order of the steps.

Characteristics of the Test Signal

In an embodiment, numerous test signals can be used for the calibration steps including: simple monotone frequencies, white noise, bandwidth limited noise, and others. Preferably, the test signal attribute generates a strong correlation peak and matched filtering performance supporting accurate time measurements especially in the presence of noise outside the probe's frequency response. In addition, by correlating the signal with the received signal in a form of matched filter, the system is able to reject room noise that is outside the band of the test signal.

In another embodiment, the test signal has a flat frequency response band that causes the signal to be easily discernable from other noise existing within the vicinity of the calibration system. The sharp central peak in the autocorrelation enables precise time localization, and the analytic characteristics of the signal allow quick and precise calculation of the system's frequency and impulse responses. Preferably, the test signal has an auto-convolution peak and a bandwidth complementary to the noise floor in the space.

Calculating the Relative Gain, Time Delays, and Frequency Responses

In an embodiment, the calibration system accommodates a known listening position for the desired acoustics level. For example, a given location in a user's home will be designated as a preferred listening position. Thereafter, the time it takes for sound from each speaker to reach the preferred listening position can be calculated with the calibration computing device. Thus, with correction applied, the sound from each speaker will reach the preferred listening position simultaneously if the sound occurs simultaneously in each channel of the program material. Given the calculations made by the calibration computing device, the time delays and gain in each speaker can be adjusted in order to cause the sound generated from each speaker to reach the preferred listening position simultaneously with the same acoustic level if the sound occurs simultaneously and at the same level in each channel of the program material.

In another embodiment, the signal specified for use in calibration can be used with one or more rendering devices and a single microphone. The system may instruct each rendering device in turn to emit a calibration pulse of a bandwidth appropriate for the rendering device. For determining the appropriate bandwidth, the calibration system may use a wideband calibration pulse and measure the bandwidth, and then adjust the bandwidth as needed. Alternatively, the calibration system may also use a mid band calibration pulse. By using the first arrival portion of the calibration pulse, the calibration system can calculate the time delay, gain, and frequency response of the surround sound or other speaker system to the microphone. Based on that calculation, an inverse filter (LPC, ARMA, or other filter that exists in the art) that partially reverses the frequency errors of the sound system can be calculated, and used in the sound system, along with delay and gain compensation, to equalize the acoustic performance of the rendering device and its surroundings.

For calculating the relative time delay, a probe signal is sent through each rendering device. In turn, each rendering device emits a pulse. At the same time, a microphone is recording the emitted pulse as actually reproduced at the microphone position. The signal captured at the microphone is sent to the calibration computing device.

At the calibration computing device, the time delay determination module 206 analyzes the Fourier transform of the calibration pulse, or emitted pulse, and the captured signal. The Fourier transform of the captured signal is multiplied by the conjugate of the Fourier transform of the calibration pulse (or, equivalently, divided by the Fourier transform of the calibration pulse). The resulting product or ratio is the complex system response. As the pulse is band-limited, noise outside the frequency range of the pulse is strongly rejected. As a result, the structure of the probe signal makes it easier to recognize the peaks of the signals by rejecting air conditioning and other typical forms of room noise.

The analytic envelope of the product is then calculated, and used to find the first arrival peak from the loudspeaker. The analytic envelope is computed from the complex system response as follows. The complex system response has a positive frequency half and a negative frequency half. The negative frequency half of the complex frequency response is removed by zeroing out this half. The inverse complex Fourier transform of the result is the complex analytic envelope. The analytic energy envelope is then created by taking the product of the complex analytic envelope and its complex conjugate. Alternatively, the analytic energy envelope can be calculated by taking the sum of squares of the real and complex parts.

The time delay determination module 206 then finds the time-domain peaks from each speaker by looking for peaks in the analytic energy envelope. Alternatively, the square root (or any other positive power) of the analytic energy envelope can be used for the same purpose, since the location of the peaks of a function do not change if the value of the function is raised to some fixed power at every point. Any negative power of the analytic energy envelope can also be used if the search is modified to look for dips instead of peaks.

Once the captured signal and the calibration pulse are convolved with each other and the delays are measured, a new, broadband probe signal is created. The new probe signal is used to probe the system as before, and then to generate an inverse filter. The inverse filter includes any correction filter that is capable of correcting frequency response errors in the speaker and acoustics of a listening environment.

The analytic energy envelope of the broadband response is then computed using a method similar to the one described earlier. Peaks in the analytic energy envelope are located using any of the methods described earlier. Based on the time differences and amplitude differences of the peaks, the relative time delays and amplitudes for the first-reflection correction can be established.

For calculating the frequency response, the room is probed, one speaker sequentially after another, with a broadband pulse. In an embodiment, the probe actually consists of two pulses. For example, a narrowband first pulse is used to locate the time axis of the captured room characteristics and the midband gain. Preferably, the first pulse is a limited bandwidth pulse. A second pulse is used to measure the frequency response and other appropriate characteristics of the system. Preferably, the second pulse is a wideband pulse. Alternatively, other pulses may be used.

Once the time delay and gain are set, the limited bandwidth pulse is discarded and the broadband pulse is analyzed. Next, the microphone is monitored without any output to determine the noise floor. At this point, the total power (RMS) of the analytic signal is measured around the main peak from each speaker. This allows the reverberant part of each speaker's output to be rejected and therefore provides good imaging. The smallest of the channel gains can be computed. As such, each channel gain adjustment factor is calculated from the smallest of the channel gains and recorded as the gain.

For calculating the first-reflection cancellation filters, the reflection detection module 212 calculates the time delay of the largest peak in the first-reflection, and its corresponding amplitude is used to set the reflection cancellation filter strength. Preferably, the first reflection cancellation filter is an Infinite Impulse Response (IIR) filter. When error conditions arise, the first-reflection correction is disabled for that speaker and its corresponding symmetric partner. The predesigned tap weights of the IIR filter ensure stability and frequency control of the first-reflection corrections. In an embodiment, the filter can be parameterized in terms of first reflection delay and first reflection strength, which can then be directly applied with the predefined tap weights in order to implement first reflection cancellation. Preferably, the first-reflection cancellation filters are recursive filters that generate a signal with an opposite sign and amplitude to partially cancel the reflection of the emitted signal.

For calculating the absolute or relative frequency response, the broadband pulse is transformed into power spectra by applying a Fourier transform operation. Note that the term “power spectra” is sometimes referred to as “frequency response”. When the term “spectra” or “spectrum” is used here, it refers to the complex Fourier Spectrum, not the power spectrum, unless it is specifically stated as “power spectrum”. Preferably, the power response is limited to 20 dB above and 10 dB below the narrowband energy band values. Next, the noise response is subtracted out (it is important that the noise response be scaled appropriately prior to subtraction, unless the probe signal was scaled to a magnitude of one before computing the complex system response). In turn, the power response is aggregated together to create a global power response. The global power response is divided by the number of main channels to create the mean power response. Each speaker's relative frequency response can be calculated by dividing its frequency response by the mean frequency response. Alternatively, the relative frequency calculation may be omitted if a high quality microphone is used.

Preferably, each frequency response is separated into two parts. For example, the spectra may be separated into two spectra, a flattened spectrum above 1200 with a linear window interpolating to the actual spectra below 800 Hz for the first spectrum, and the second being the converse, including the high frequency information and excluding (flattening) the low frequency spectrum.

The modified spectra are then used to generate LPC predictors as described above, based on the resulting autocorrelations. In an embodiment, the two filters generated from the two flattened spectra are convolved together to acquire a correction filter for each channel. Preferably, the gain of a correction filter is equalized to 1 at about 1 kHz in order to allow gain control separately from the LPC predictor gain. Preferably, the correction filters include Finite Impulse Response (FIR) filters.

After the room correction parameters such as gain, time delays, frequency responses, and appropriate correction filters are calculated, a room correction profile is created based on these parameters. The room correction profile contains correction information that corresponds to the parameters. The room correction profile is stored in memory or other storage means until it is used for processing. The room correction profile acts as one of two inputs to a render-side room correction module. The render-side room correction module includes any processor that is capable of processing a signal and providing computations. The other input is digital audio content data. The audio content data includes any digital audio data source such as music CD, MP3 file, or any data source that provides audio content. In an embodiment, the render-side module is stored in the calibration module 200. Alternatively, the render-side module can be placed in any storage means attached to a processor or anywhere in the calibration computing device.

Once the render-side room correction module receives the room correction profile input and the audio content data input, the render-side module processes the data to apply the proper adjustments for improving the quality of the acoustic level of the audio system. Some examples of making these adjustments are adjusting the delay for the rendering devices such that the audio generated by each speaker reaches a preferred listening position simultaneously; creating an inverse filter using the time delay, gain, and frequency response characteristics for correcting one or more frequency errors of the sound system; and equalizing the speaker gain by adjusting the gain for the rendering devices.

The invention is described in the general context of computer-executable instructions, such as program modules, being executed by a computer. Generally, program modules include routines, programs, objects, components, data structures, etc. that perform particular tasks or implement particular abstract data types. Moreover, those skilled in the art will appreciate that the invention may be practiced with other computer system configurations, including hand-held devices, multiprocessor systems, microcontroller-based, microprocessor-based, or programmable consumer electronics, minicomputers, mainframe computers, and the like. The invention may also be practiced in distributed computing environments where tasks are performed by remote processing devices that are linked through a communications network. In a distributed computing environment, program modules may be located in both local and remote computer storage media including memory storage devices.

While particular embodiments of the invention have been illustrated and described in detail herein, it should be understood that various changes and modifications might be made to the invention without departing from the scope and intent of the invention. The embodiments described herein are intended in all respects to be illustrative rather than restrictive. Alternate embodiments will become apparent to those skilled in the art to which the present invention pertains without departing from its scope.

From the foregoing it will be seen that this invention is one well adapted to attain all the ends and objects set forth above, together with other advantages, which are obvious and inherent to the system and method. It will be understood that certain features and sub-combinations are of utility and may be employed without reference to other features and sub-combinations. This is contemplated and within the scope of the appended claims.

The invention claimed is:

1. A method for improving the listening environment of a sound system comprising:
generating a calibration pulse from one or more rendering devices, the calibration pulse having an autoconvolution peak and a bandwidth complimentary to the noise floor in the space;
capturing the calibration pulse at a microphone attached to a calibration computing device;
calculating at least one of: a time delay, gain, and frequency response characteristic corresponding to the sound system using the captured calibration pulse; and
adjusting at least one of: the time delays, gain, and frequency response characteristic of the rendering devices to cause the sound generated from the rendering devices to reach a listener's acoustic preference.

2. The method of claim 1, further comprising: adjusting the delays for the rendering devices such that the audio content generated by each rendering device reaches a preferred listening position simultaneously.

3. The method of claim 1, further comprising: creating an inverse filter using the time delays, gain, and frequency response characteristics for correcting one or more frequency errors of the sound system.

4. The method of claim 3, wherein creating an inverse filter further comprises calculating a first LPC filter by flattening a frequency spectrum at low frequencies.

5. The method of claim 4, wherein creating an inverse filter further comprises calculating a second LPC filter by flattening a frequency spectrum at high frequencies.

6. The method of claim 5, wherein creating an inverse filter further comprises convolving the first LPC filter with the second LPC filter to generate an inverse filter.

7. The method of claim 1, further comprising: equalizing the acoustic performance of the rendering devices by adjusting the gain for the rendering devices.

8. The method of claim 1, further comprising: measuring the gain directly from the rendering devices using the calibration pulse.

9. The method of claim 1, further comprising obtaining a bandwidth for the calibration pulse by using a mid band probe signal.

10. A method for calibrating a sound system comprising:
generating a test signal from one or more rendering devices;
capturing the test signal at a microphone attached to a calibration computing device, the captured test signal having a first arrival portion;
transmitting the captured test signal to the calibration computing device;
calculating an inverse filter using the first arrival portion of the test signal at the calibration computing device;
generating a room correction profile at the calibration computing device; and
adjusting the time delay, gain, and frequency response characteristics of the rendering devices using the room correction profile.

11. The method of claim 10, wherein calculating an inverse filter further comprises: calculating a first LPC filter by flattening a frequency spectrum at low frequencies.

12. The method of claim 11, wherein calculating an inverse filter further comprises: calculating a second LPC filter by flattening a frequency spectrum at high frequencies.

13. The method of claim 12, wherein calculating an inverse filter further comprises: convolving the first LPC filter with the second LPC filter to generate an inverse filter.

14. The method of claim 10, wherein generating a room correction profile further comprises: calculating the analytic energy envelope using the calculated energy corresponding to the inverse filter.

15. The method of claim 10, further comprising: measuring the gain directly from the rendering devices using the test signal.

16. The method of claim 10, further comprising obtaining a bandwidth for the test signal by using a mid band probe signal.

17. The method of claim 14, wherein calculating the gain is based on the analytic energy envelope.
